(19) United States
(12) Patent Application Publication
(10) Pub. No.: US 2022/0004884 A1
(43) Pub. Date: Jan. 6, 2022

(54) Convolutional Neural Network Computing Acceleration Method and Apparatus, Device, and Medium

(71) Applicant: CANAAN BRIGHT SIGHT CO., LTD, Beijing (CN)

(72) Inventors: Hui GUO, Beijing (CN); Nangeng ZHANG, Beijing (CN)

(21) Appl. No.: 17/290,351

(22) PCT Filed: Sep. 17, 2019
(86) PCT No.: PCT/CN2019/106083

§ 371 Date: May 12, 2021

(30) Foreign Application Priority Data
Oct. 31, 2018 (CN) 201811286575.9

(51) Int. Cl. G06N 3/10; G06F 5/01

(52) U.S. Cl. CPC G06N 3/10; G06F 5/01

(57) ABSTRACT

Disclosed in the present application are a convolutional neural network computing acceleration method and apparatus, a device, and a medium. The method at least comprises: quantizing an original input tensor and convolution kernel by using a first function to obtain an input tensor and convolution kernel in a fixed-point number form; computing respective quantization offsets of the input tensor and convolution kernel in the fixed-point number form by using a second function, wherein the first function and the second function comprise corresponding quantization scaling factors, and conversion logic for converting a floating-point number into a fixed-point number; computing a first convolution result of the input tensor and convolution kernel in the fixed-point number form according to the quantization offsets; and computing a second convolution result of the original input tensor and convolution kernel according to the quantization scaling factors and the first convolution kernel.

### TECHNICAL FIELD

The present disclosure relates to the field of machine learning technologies, and in particular to a method, an apparatus, a device, and a medium each for accelerating computation of a convolutional neural network.

### BACKGROUND

Convolutional neural network has achieved huge breakthroughs in many fields such as computer vision, speech processing, machine learning, image recognition, and face recognition, which significantly improves the performances of corresponding machine algorithms in various tasks such as image classification, target detection and speech recognition, and has been widely applied in industries such as Internet and video surveillance.

The convolutional neural network with a larger capacity and a higher complexity can learn data more comprehensively and thereby recognize the data more accurately. Of course, as the number of network layers and parameters increase, the costs in computation and storage may also increase significantly.

In the prior art, floating-point numbers are generally used directly for the convolution computation while processing data by using the convolutional neural network. However, this method has a slow computation speed and high hardware power consumption.

### SUMMARY

Embodiments of the present disclosure provide a method, an apparatus, a device, and a medium each for accelerating computation of a convolutional neural network to solve the technical problem in the prior art, which lies in the fact that floating-point numbers are generally used directly for the convolution computation while processing data by using the convolutional neural network, which however has a slow computation speed and high hardware power consumption.

The technical solutions adopted by embodiments of the present disclosure are as follows:

A method for accelerating computation of a convolutional neural network, including:

quantizing an original input tensor and an original convolution kernel by using a first function to acquire an input tensor and a convolution kernel that are in a fixed-point number form;

calculating respective quantization offsets of the input tensor and the convolution kernel in the fixed-point number form by using a second function, where the first function and the second function include respective quantization scaling coefficients, and respective conversion logics for converting a floating-point number into a fixed-point number;

calculating based on the quantization offsets a first convolution result of the input tensor and the convolution kernel that are in the fixed-point number form; and

calculating a second convolution result of the original input tensor and the original convolution kernel based on the quantization scaling coefficients and the first convolution result.

Optionally, the quantization scaling coefficients include a first quantization coefficient for the original input tensor and a second quantization coefficient for the original convolution kernel, where

the first quantization coefficient is calculated based on an end value of a specified quantized value range and an end value of the original input tensor, and/or

the second quantization coefficient is calculated based on the end value of the specified quantized value range and an end value of the original convolution kernel.

Optionally, the end value of the quantized value range is calculated based on a specified quantization bit number.

Optionally, the specified quantization bit number is a number w of quantization bits of a specified N-nary number, and the end value of the quantized value range is calculated according to following Formula:

Q_{low}=−N^{w-1};

Q_{high}=N^{w-1}−1;

where Q_{low} represents a minimum value of the quantized value range, and Q_{high} represents a maximum value of the quantized value range.

Optionally, the first quantization coefficient is calculated according to Formula

$${S}_{X} = \frac{{Q}_{high} - {Q}_{low}}{{X}_{max} - {X}_{min}} ,$$

and/or

the second quantization coefficient is calculated according to Formula

$${S}_{W} = \frac{{Q}_{high} - {Q}_{low}}{{W}_{max} - {W}_{min}} \text{;}$$

where S_{X} represents the first quantization coefficient; S_{W} represents the second quantization coefficient; Q_{low} represents the minimum value of the quantized value range; Q_{high} represents the maximum value of the quantized value range; Xₘᵢₙ represents a minimum value of the original input tensor; Xₘₐₓ represents a maximum value of the original input tensor; Wₘᵢₙ represents a minimum value of the original convolution kernel; and Wₘₐₓ represents a maximum value of the original convolution kernel.

Optionally, in addition to the quantization scaling coefficients, the first function and/or the second function further includes the minimum value of the quantized value range and a minimum value of an object to be quantized, where the object is the original input tensor or the original convolution kernel.

Optionally, the first function is expressed as:

\dot{α}=round[S_{α}·(α−αₘᵢₙ)]+Q_{low};

where α represents the object; \dot{α} represents a quantized α; αₘᵢₙ represents a minimum value of α; S_{α} represents a quantization scaling coefficient for α; Q_{low} represents the minimum value of the quantized value range; and round represents a function for rounding the floating-point number to the fixed-point number.

Optionally, the second function is expressed as:

B_{α}=round[−S_{α}˜αₘᵢₙ]+Q_{low};

where B_{α} represents a quantization offset calculated for the quantized α; αₘᵢₙ represents a minimum value of α; S_{α} represents a quantization scaling coefficient for α; Q_{low} represents the minimum value of the quantized value range; and round represents a function for rounding the floating-point number to the fixed-point number.

Optionally, calculating based on the quantization offsets the first convolution result of the input tensor and the convolution kernel in the fixed-point number form specifically includes:

calculating the first convolution result of the input tensor and the convolution kernel in the fixed-point number form according to following Formula:

\dot{Y}=conv(\dot{X}−B_{X},\dot{W}−B_{W});

where \dot{Y} represents the first convolution result; \dot{X} represents the input tensor in the fixed-point number form; \dot{W} represents the convolution kernel in the fixed-point number form; B_{X} represents a quantization offset calculated for the input tensor in the fixed-point number form; B_{W} represents the quantization offset calculated for the convolution kernel in the fixed-point number form; and conv represents a convolution calculating function.

Optionally, calculating the second convolution result of the original input tensor and the original convolution kernel based on the quantization scaling coefficients and the first convolution result specifically includes:

calculating the second convolution result of the original input tensor and the original convolution kernel according to following Formula:

$$Y = \frac{\dot{Y}}{{S}_{X} \cdot {S}_{W}} ;$$

where Y represents the second convolution result; S_{X} represents a quantization scaling coefficient for the original input tensor; and S_{W} represents a quantization scaling coefficient for the original convolution kernel.

An apparatus for accelerating computation of a convolutional neural network, including:

a quantization module configured to quantize an original input tensor and an original convolution kernel by using a first function to acquire an input tensor and a convolution kernel that are in a fixed-point number form;

a quantization offset module configured to calculate respective quantization offsets of the input tensor and the convolution kernel that are in the fixed-point number form by using a second function, where the first function and the second function include respective quantization scaling coefficients, and respective conversion logics for converting a floating-point number into a fixed-point number;

a first convolution module configured to calculate based on the quantization offsets a first convolution result of the input tensor and the convolution kernel that are in the fixed-point number form; and

a second convolution module configured to calculate a second convolution result of the original input tensor and the original convolution kernel based on the quantization scaling coefficients and the first convolution result.

Optionally, the quantization scaling coefficients include a first quantization coefficient for the original input tensor and a second quantization coefficient for the original convolution kernel, where

the first quantization coefficient is calculated based on an end value of a specified quantized value range and an end value of the original input tensor, and/or

the second quantization coefficient is calculated based on the end value of the specified quantized value range and an end value of the original convolution kernel.

Optionally, the end value of the quantized value range is calculated based on a specified quantization bit number.

Optionally, the specified quantization bit number is a number w of quantization bits of a specified N-nary number, and the quantization module calculates the end value of the quantized value range according to following Formula:

Q_{low}=−N^{w-1};

Q_{high}=N^{w-1}−1;

where Q_{low} represents a minimum value of the quantized value range, and Q_{high} represents a maximum value of the quantized value range.

Optionally, the first quantization coefficient is calculated according to Formula

$${S}_{X} = \frac{{Q}_{high} - {Q}_{l o w}}{{X}_{max} - {X}_{min}} ,$$

and/or

the second quantization coefficient is calculated according to Formula

$${S}_{W} = \frac{{Q}_{high} - {Q}_{l o w}}{{W}_{max} - {W}_{min}} ;$$

where S_{X} represents the first quantization coefficient; S_{W} represents the second quantization coefficient; Q_{low} represents the minimum value of the quantized value range; Q_{high} represents the maximum value of the quantized value range; Xₘᵢₙ represents a minimum value of the original input tensor; Xₘₐₓ represents a maximum value of the original input tensor; Wₘᵢₙ represents a minimum value of the original convolution kernel; and Wₘₐₓ represents a maximum value of the original convolution kernel.

Optionally, in addition to the quantization scaling coefficients, the first function and/or the second function further includes the minimum value of the quantized value range and a minimum value of an object to be quantized, where the object is the original input tensor or the original convolution kernel.

Optionally, the first function is expressed as:

\dot{α}=round[S_{α}·(α−αₘᵢₙ)]+Q_{low};

where α represents the object; \dot{α} represents a quantized α; αₘᵢₙ represents a minimum value of α; S_{α} represents a quantization scaling coefficient for α; Q_{low} represents the minimum value of the quantized value range; and round represents a function for rounding the floating-point number to the fixed-point number.

Optionally, the second function is expressed as:

B_{α}=round[−S_{α}·αₘᵢₙ]+Q_{low};

where B_{α} represents quantization offsets calculated for the quantized α; αₘᵢₙ represents a minimum value of α; S_{α} represents a quantization scaling coefficient for α; Q_{low} represents the minimum value of the quantized value range; and round represents a function for rounding the floating-point number to the fixed-point number.

Optionally, calculating the first convolution result of the input tensor and the convolution kernel that are in the fixed-point number form by the first convolution module based on the quantization offsets specifically includes:

calculating the first convolution result of the input tensor and the convolution kernel that are in the fixed-point number form by the first convolution module according to following Formula:

\dot{Y}=conv(\dot{X}−B_{X},\dot{W}−B_{W});

where \dot{Y} represents the first convolution result; \dot{X} represents the input tensor in the fixed-point number form; \dot{W} represents the convolution kernel in the fixed-point number form; B_{X} represents a quantization offset calculated for the input tensor in the fixed-point number form; B_{W} represents the quantization offset calculated for the convolution kernel in the fixed-point number form; and conv represents a convolution calculating function.

Optionally, calculating the second convolution result of the original input tensor and the original convolution kernel by the second convolution module based on the quantization scaling coefficients and the first convolution result specifically includes:

calculating the second convolution result of the original input tensor and the original convolution kernel by the second convolution module according to following Formula:

$$Y = \frac{\dot{Y}}{{S}_{X} \cdot {S}_{W}} ;$$

where Y represents the second convolution result; S_{X} represents a quantization scaling coefficient for the original input tensor; and S_{W} represents a quantization scaling coefficient for the original convolution kernel.

A device for accelerating computation of a convolutional neural network, including:

at least one processor; and

a memory communicatively connected with the at least one processor and having instructions executable by the at least one processor stored therein, where the instructions, when executed by the at least one processor, enable the at least one processor to:

quantize an original input tensor and an original convolution kernel by using a first function to acquire an input tensor and a convolution kernel that are in a fixed-point number form;

calculate respective quantization offsets of the input tensor and the convolution kernel that are in the fixed-point number form by using a second function, where the first function and the second function include respective quantization scaling coefficients, and respective conversion logics for converting a floating-point number into a fixed-point number;

calculate based on the quantization offsets a first convolution result of the input tensor and the convolution kernel that are in the fixed-point number form; and

calculate a second convolution result of the original input tensor and the original convolution kernel based on the quantization scaling coefficients and the first convolution result.

A non-volatile computer storage medium for accelerating computation of a convolutional neural network, having computer-executable instructions stored therein, where the computer-executable instructions being configured to:

quantize an original input tensor and an original convolution kernel by using a first function to acquire an input tensor and a convolution kernel that are in a fixed-point number form;

calculate respective quantization offsets of the input tensor and the convolution kernel that are in the fixed-point number form by using a second function, where the first function and the second function include respective quantization scaling coefficients, and respective conversion logics for converting a floating-point number into a fixed-point number;

calculate based on the quantization offsets a first convolution result of the input tensor and the convolution kernel that are in the fixed-point number form; and

calculate a second convolution result of the original input tensor and the original convolution kernel based on the quantization scaling coefficients and the first convolution result.

According to at least one technical solution provided in embodiments of the present disclosure, the beneficial effects of facilitating improvement of the convolution computation speed and algorithm performance and reduction of the power consumption and design difficulty of the hardware can be achieved by using the conversion logic for converting the floating-point number into the fixed-point number and the adaptive quantization based on quantization offsets.

### BRIEF DESCRIPTION OF THE DRAWINGS

Here, the accompanying drawings are illustrated to provide further understanding of the present disclosure, which constitute a part of the specification. The exemplary embodiments of the present disclosure and the descriptions thereof are used to explain the present disclosure, and do not constitute improper limitation to the present disclosure. In the accompanying drawings:

FIG. 1 is a schematic flowchart of a method for accelerating computation of a convolutional neural network according to some embodiments of the present disclosure;

FIG. 2 is a schematic structural diagram of an apparatus, corresponding to FIG. 1, for accelerating computation of a convolutional neural network according to some embodiments of the present disclosure; and

FIG. 3 is a schematic structural diagram of a device, corresponding to FIG. 1, for accelerating computation of a convolutional neural network according to some embodiments of the present disclosure.

### DETAILED DESCRIPTION

In order to make the objects, technical solutions and advantages of the present disclosure more apparent, the technical solutions of the present disclosure will be clearly and completely described below with reference to the embodiments and corresponding drawings of the present disclosure. It is apparent that the described embodiments are merely a part but not all of the embodiments of the present disclosure. All the other embodiments achieved by a person of ordinary skill in the art, based on the embodiments of the present disclosure without creative effort, shall fall within the protection scope of the present disclosure.

The convolution computation is a commonly used computation in image processing. For an input image, each pixel in the image output by any layer of the convolutional neural network may be a weighted average of pixels in a small area in the input image, the weights of which are defined by a function called convolution kernel. The process of performing convolution computation on an image includes acquiring an input image and a convolution kernel expressed as a matrix; and performing operations such as multiplication and addition with a predetermined step length on the input image and the convolution kernel according to convolution rules to thereby acquire a convolution result.

According to the present disclosure, the aforesaid convolution computation is not performed directly but performed approximately by converting the floating-point number to the fixed-point number and performing processing such as the adaptive quantization based on dynamic quantization offsets, which can not only accelerate the computation speed but also retain a rather good computation accuracy, thereby effectively reducing the costs in implementing and operating the convolutional neural network.

The solutions of the present disclosure will be described hereinafter in detail.

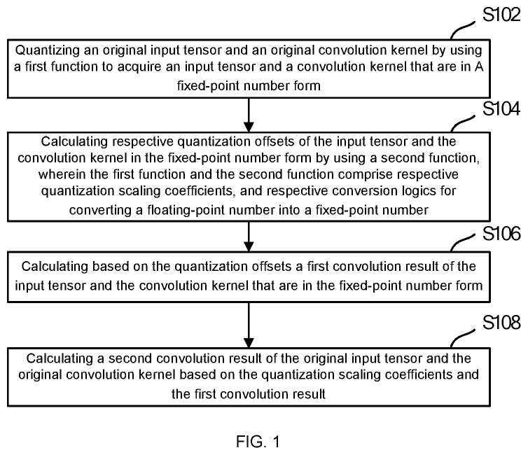

FIG. 1 is a schematic flowchart of a method for accelerating computation of a convolutional neural network according to some embodiments of the present disclosure. In this flow, the execution body, from a device perspective, may be one or more computing devices, such as a single machine learning server, a machine learning server cluster, or the like based on a convolutional neural network. Correspondingly, the execution body, from a program perspective, may be a program carried on the computing devices, such as a neural network modeling platform, an image processing platform, or the like based on a convolutional neural network, or may specifically be one or more neurons included in the convolutional neural network applied on this type of platform.

The flow in FIG. 1 may include following steps.

S102: an original input tensor and an original convolution kernel (collectively referred to as original data) are quantized by using a first function to acquire an input tensor and a convolution kernel that are in a fixed-point number form.

In some embodiments of the present disclosure, the original input tensor may be an input to an entire convolutional neural network or input to any neuron in the convolutional neural network. For the convolutional neural network, the input tensor is generally expressed as a vector or matrix, and the elements in the input tensor are generally in floating-point form.

At present, the neurons may directly perform the convolution computation on the original input tensor and the original convolution kernel (different neurons may adopt different convolution kernels) and thereby directly perform the convolution computation on the floating-point number. To the contrary, according to the present disclosure, the convolution computation is not directly performed on the original input tensor and the original convolution kernel but simplified firstly by performing some approximate processing. Then, the convolution computation is performed with the simplified data to acquire the convolution result indirectly.

In some embodiments of the present disclosure, the approximate processing at least includes quantization during which a processing of converting the floating-point number to the fixed-point number is further performed.

In some embodiments of the present disclosure, the quantization performed respectively on the original input tensor and the original convolution kernel may be different. For example, the number of quantization bits, the conversion logics for converting the floating-point number into the fixed-point number and the like may be different.

S104: respective quantization offsets of the input tensor and the convolution kernel that are in the fixed-point number form are calculated by using a second function. The first function and the second function include respective quantization scaling coefficients, and respective conversion logics for converting a floating-point number into a fixed-point number.

In some embodiments of the present disclosure, the quantization offsets may be dynamically changed to be adaptive to the current input tensor and convolution kernel. The quantization offset is adopted to further adaptively adjust the preliminary quantization result in step S102, such that the final quantization result acquired after the adjustment is closer to the original data, thereby facilitating improvement of the computation accuracy.

In some embodiments of the present disclosure, the quantization scaling coefficient mainly determines the scale of the original data after transformation, and there may be various methods for calculating the quantization scaling coefficient. For example, the quantization scaling coefficient may be calculated according to a predetermined quantized value range and/or a value range of the object to be quantized per se. There may also be various conversion logics for converting the floating-point number to the fixed-point number, and the conversion may for example be performed by rounding or directly rounding off the mantissa, etc.

S106: a first convolution result of the input tensor and the convolution kernel that are in the fixed-point number form are calculated based on the quantization offsets.

S108: a second convolution result of the original input tensor and the original convolution kernel are calculated based on the quantization scaling coefficients and the first convolution result. The second convolution result may serve as the output of the current neuron.

In some embodiments of the present disclosure, the original input tensor and the original convolution kernel are not directly subjected to the convolution computation. Instead, the convolution result of the original input tensor and the original convolution kernel is indirectly calculated to approximation based on a convolution computation result of the aforesaid final quantization result, so as to reduce the amount of computation and thereby reduce errors of the convolution computation caused by the quantization.

According to the method of FIG. 1, the conversion logic for converting the floating-point number into the fixed-point number and the adaptive quantization based on quantization offsets are used, which can facilitate improvement of the convolution computation speed and algorithm performance and reduction of the power consumption and design difficulty of the hardware.

Based on the method in FIG. 1, some embodiments of the present application further provide some specific implementation solutions and extension solutions of the method, which will be described below.

In some embodiments of the present disclosure, a quantized value range may be specified in advance and then quantization is performed accordingly. The data acquired after the quantization may fall in the quantized value range that is discrete. The quantization can be achieved by mapping the value range of the original data with the quantized value range.

Assuming that the input tensor and the convolution kernel are quantized respectively with different quantization parameters (which may for example be quantization scaling coefficients or may be other parameters such as the trim coefficients after the quantization and scaling), the quantization scaling coefficient may for example include a first quantization coefficient for the original input tensor and a second quantization coefficient for the original convolution kernel. Furthermore, the first quantization coefficient is calculated, for example, based on the end value of the specified quantized value range and the end value of the original input tensor; and/or the second quantization coefficient is calculated based on the end value of the specified quantized value range and the end value of the original convolution kernel.

The end value includes at least one of the minimum value and the maximum value, which may be determined by traversing each element in the input tensor or the convolution kernel. The smallest element may serve as the minimum value, and the largest element may serve as the maximum value.

In some embodiments of the present disclosure, the end value of the quantized value range is calculated based on a specified quantization bit number. The number of quantization bits is generally the number of binary bits, such as 8-bit, 16-bit, or 32-bit binary. In general, the higher the number of bits, the higher the accuracy of quantization.

It is assumed that the specified quantization bit number is a number w of quantization bits of a specified N-nary number. For example, the end value of the quantized value range may be calculated according to following Formula: Q_{low}=−N^{w-1} and Q_{high}=N^{w-1}−1, where Q_{low} represents the minimum value of the quantized value range, Q_{high} represents the maximum value of the quantized value range, and N is generally 2. The negative value is considered in this example. In practical applications, it is also possible to merely consider the value range of positive values.

In some embodiments of the present disclosure, the quantization scaling coefficient may be defined based on uniform quantization or non-uniform quantization. As an example of defining the quantization scaling coefficient based on uniform quantization, the first quantization coefficient may be calculated according to Formula

$${S}_{X} = \frac{{Q}_{high} - {Q}_{l o w}}{{X}_{max} - {X}_{min}} ,$$

and the second quantization coefficient may be calculated according to Formula

$${S}_{W} = \frac{{Q}_{high} - {Q}_{l o w}}{{W}_{max} - {W}_{min}} ,$$

where X represents the original input tensor; W represents the original convolution kernel; S_{X} represents the first quantization coefficient; S_{W} represents the second quantization coefficient; Q_{low} represents the minimum value of the quantized value range; Q_{high} represents the maximum value of the quantized value range; Xₘᵢₙ represents a minimum value of the original input tensor; Xₘₐₓ represents a maximum value of the original input tensor; Wₘᵢₙ represents a minimum value of the original convolution kernel; and Wₘₐₓ represents a maximum value of the original convolution kernel.

As an example of defining the quantization scaling coefficient based on non-uniform quantization, the coefficients or additional items containing the current X or W may for example be added to the Formula in the former example.

In some embodiments of the present disclosure, the first function and/or the second function in FIG. 1 includes respective quantization scaling coefficients. In addition, besides the quantization scaling coefficients, the first function and/or the second function may further include other factors such as the minimum value of the quantized value range and the minimum value of the object to be quantized, the object herein referring to the original input tensor or the original convolution kernel.

More intuitively, the present disclosure provides an example of a first function and a second function as applied in an actual application scenario.

The first function may for example be expressed as:

\dot{α}=round[S_{α}·(α−αₘᵢₙ)]+Q_{low};

where α represents the object; a represents a quantized α; αₘᵢₙ represents the minimum value of α; S_{α} a represents a quantization scaling coefficient for α; Q_{low} represents a minimum value of the quantized value range, and round represents a function for rounding the floating-point number to the fixed-point number.

The second function may for example be expressed as:

B_{α}=round[−S_{α}·αₘᵢₙ]+Q_{low};

where B_{α} represents the quantization offsets calculated for the quantized α; αₘᵢₙ represents the minimum value of α; S_{α} represents the quantization scaling coefficient for α; and Q_{low} represents the minimum value of the quantized value range.

The round may be replaced by other functions that can convert the floating-point number to the fixed-point number. While quantizing the original input tensor and further calculating the quantization offset, α may be X and while quantizing the original convolution kernel and further calculating the quantization offset, a may be W.

In some embodiments, step S106 of calculating based on the quantization offsets the first convolution result of the input tensor and the convolution kernel that are in the fixed-point number form may for example include:

calculating the first convolution result of the input tensor and the convolution kernel that are in the fixed-point number form according to following Formula:

\dot{Y}=conv(\dot{X}−B_{X},\dot{W}−B_{W});

where \dot{Y} represents the first convolution result; \dot{X} represents the input tensor in the fixed-point number form; \dot{W} represents the convolution kernel in the fixed-point number form; B_{X} represents the quantization offset calculated for the input tensor in the fixed-point number form; B_{W} represents the quantization offset calculated for the convolution kernel in the fixed-point number form; and conv represents a convolution calculating function. Herein, \dot{X}−B_{X} and \dot{W}−B_{W} may represent the final quantization results of X and W, respectively, and the first convolution result may be acquired by directly performing convolution computation on the final quantization result.

In some embodiments of the present disclosure, the first convolution result \dot{Y} may serve as the output of the current neuron. However, considering that the quantization may cause loss of data accuracy, the first convolution result \dot{Y} calculated based on the final quantization result may correspondingly also has a loss from the real result (i.e., a result acquired directly by performing a convolution computation on X and W through conv) in practice. In order to reduce the loss as much as possible, a second convolution result Y which is relatively closer to the real result may be acquired by further restoring \dot{Y} with a quantization scaling coefficient to a certain extent in the reverse direction.

Under this consideration, step S108 of calculating the second convolution result of the original input tensor and the original convolution kernel based on the quantization scaling coefficients and the first convolution result may for example include:

calculating the second convolution result of the original input tensor and the original convolution kernel according to following Formula:

$$Y = \frac{\dot{Y}}{{S}_{X} \cdot {S}_{W}} ;$$

where Y represents the second convolution result; S_{X} represents the quantization scaling coefficient for the original input tensor; and S_{W} represents the quantization scaling coefficient for the original convolution kernel.

It should be noted that some formulas listed above may reflect the concept of the solution of the present disclosure, but are not the only implementation manner. Based on the concept of the solution of the present disclosure, some more similar formulas may be acquired to replace the formulas listed above.

Based on the same concept, some embodiments of the present disclosure further provide an apparatus, a device, and a non-volatile computer storage medium each corresponding to the aforesaid method.

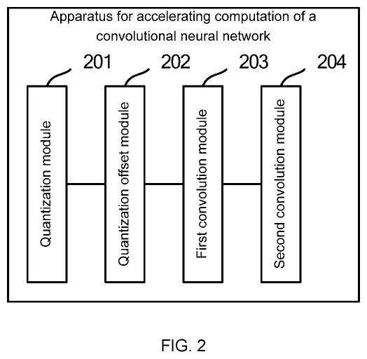

FIG. 2 is a schematic structural diagram of an apparatus corresponding to FIG. 1 for accelerating computation of a convolutional neural network according to some embodiments of the present disclosure. The apparatus includes:

a quantization module 201 configured to quantize an original input tensor and an original convolution kernel by using a first function to acquire an input tensor and a convolution kernel that are in a fixed-point number form;

a quantization offset module 202 configured to calculate respective quantization offsets of the input tensor and the convolution kernel that are in the fixed-point number form by using a second function, where the first function and the second function include respective quantization scaling coefficients, and respective conversion logics for converting a floating-point number into a fixed-point number;

a first convolution module 203 configured to calculate based on the quantization offsets a first convolution result of the input tensor and the convolution kernel that are in the fixed-point number form; and

a second convolution module 204 configured to calculate a second convolution result of the original input tensor and the original convolution kernel based on the quantization scaling coefficients and the first convolution result.

Optionally, the quantization scaling coefficients include a first quantization coefficient for the original input tensor and a second quantization coefficient for the original convolution kernel;

the first quantization coefficient is calculated based on an end value of a specified quantized value range and an end value of the original input tensor, and/or

the second quantization coefficient is calculated based on the end value of the specified quantized value range and an end value of the original convolution kernel.

Optionally, the end value of the quantized value range is calculated based on a specified quantization bit number.

Optionally, the specified quantization bit number is a number w of quantization bits of a specified N-nary number, and the quantization module 201 calculates the end value of the quantized value range according to following Formula:

Q_{low}=−N^{w-1};

Q_{high}=N^{w-1}−1;

where Q_{low} represents a minimum value of the quantized value range, and Q_{high} represents a maximum value of the quantized value range.

Optionally, the first quantization coefficient is calculated according to Formula

$${S}_{X} = \frac{{Q}_{high} - {Q}_{l o w}}{{X}_{max} - {X}_{min}} ,$$

and/or

the second quantization coefficient is calculated according to Formula

$${S}_{W} = \frac{{Q}_{high} - {Q}_{l o w}}{{W}_{max} - {W}_{min}} ;$$

where S_{X} represents the first quantization coefficient; S_{W} represents the second quantization coefficient; Q_{low} represents the minimum value of the quantized value range; Q_{high} represents the maximum value of the quantized value range; Xₘᵢₙ represents a minimum value of the original input tensor; Xₘₐₓ represents a maximum value of the original input tensor; Wₘᵢₙ represents a minimum value of the original convolution kernel; and Wₘₐₓ represents a maximum value of the original convolution kernel.

Optionally, in addition to the quantization scaling coefficient, the first function and/or the second function further includes the minimum value of the quantized value range and a minimum value of an object to be quantized, where the object is the original input tensor or the original convolution kernel.

Optionally, the first function is expressed as:

\dot{α}=round[S_{α}·(α−αₘᵢₙ)]+Q_{low};

where α represents the object; \dot{α} represents a quantized α; αₘᵢₙ represents a minimum value of α; S_{α} represents a quantization scaling coefficient for α; Q_{low} represents the minimum value of the quantized value range; and round represents a function for rounding the floating-point number to the fixed-point number.

Optionally, the second function is expressed as:

B_{α}=round[−S_{α}·αₘᵢₙ]+Q_{low};

where B_{α} represents quantization offsets calculated for the quantized α; αₘᵢₙ represents a minimum value of α; S_{α} represents a quantization scaling coefficient for α; Q_{low} represents the minimum value of the quantized value range; and round represents a function for rounding the floating-point number to the fixed-point number.

Optionally, calculating based on the quantization offsets the first convolution result of the input tensor and the convolution kernel that are in the fixed-point number form by the first convolution module 203 specifically includes:

calculating the first convolution result of the input tensor and the convolution kernel that are in the fixed-point number form by the first convolution module according to following Formula:

\dot{Y}=conv(\dot{X}−B_{X},\dot{W}−B_{W});

where \dot{Y} represents the first convolution result; \dot{X} represents the input tensor in the fixed-point number form; \dot{W} represents the convolution kernel in the fixed-point number form; B_{X} represents the quantization offset calculated for the input tensor in the fixed-point number form; B_{W} represents the quantization offset calculated for the convolution kernel in the fixed-point number form; and conv represents a convolution calculating function.

Optionally, calculating the second convolution result of the original input tensor and the original convolution kernel by the second convolution module 204 based on the quantization scaling coefficients and the first convolution result specifically includes:

calculating the second convolution result of the original input tensor and the original convolution kernel by the second convolution module 204 according to following Formula:

$$Y = \frac{\dot{Y}}{{S}_{X} \cdot {S}_{W}} ;$$

where Y represents the second convolution result; S_{X} represents the quantization scaling coefficient for the original input tensor; and S_{W} represents the quantization scaling coefficient for the original convolution kernel.

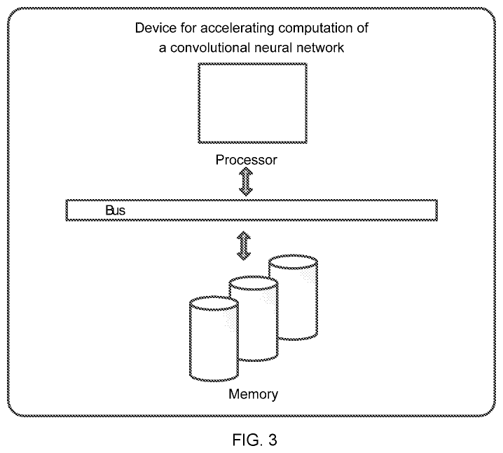

FIG. 3 is a schematic structural diagram of a device corresponding to FIG. 1 for accelerating computation of a convolutional neural network according to some embodiments of the present disclosure. The device includes:

at least one processor; and

a memory communicatively connected with the at least one processor and having instructions executable by the at least one processor stored therein, wherein the instructions, when executed by the at least one processor, enable the at least one processor to:

quantize an original input tensor and an original convolution kernel by using a first function to acquire an input tensor and a convolution kernel that are in a fixed-point number form;

calculate respective quantization offsets of the input tensor and the convolution kernel that are in the fixed-point number form by using a second function, where the first function and the second function include respective quantization scaling coefficients, and respective conversion logics for converting a floating-point number into a fixed-point number;

calculate based on the quantization offsets a first convolution result of the input tensor and convolution kernel in the fixed-point number form; and

calculate a second convolution result of the original input tensor and the original convolution kernel based on the quantization scaling coefficients and the first convolution result.

Some embodiments of the present disclosure provide a non-volatile computer storage medium corresponding to FIG. 1 for accelerating computation of a convolutional neural network, having computer-executable instructions stored therein, where the computer-executable instructions are configured to:

quantize an original input tensor and an original convolution kernel by using a first function to acquire an input tensor and convolution kernel in a fixed-point number form;

calculate respective quantization offsets of the input tensor and the convolution kernel that are in the fixed-point number form by using a second function, where the first function and the second function include respective quantization scaling coefficients, and respective conversion logics for converting a floating-point number into a fixed-point number;

calculate based on the quantization offsets a first convolution result of the input tensor and the convolution kernel that are in the fixed-point number form; and

calculate a second convolution result of the original input tensor and the original convolution kernel based on the quantization scaling coefficients and the first convolution result.

The respective embodiments of the present disclosure are described in a progressive manner. The reference may be made to each other for the same or similar parts of the respective embodiments, and each embodiment focuses on the differences from other embodiments. Especially, for the embodiments of the apparatus, device and medium, since they basically correspond to the embodiments of the method, they are described in a simple way, and reference may be made to the description part on embodiments of the method for relevant points.

The apparatus, device and medium according to embodiments of the present disclosure correspond to the method one by one. Thus, the apparatus, device and medium have similar beneficial technical effects with the corresponding method. Since the beneficial technical effects of the method have been described in detail above, the beneficial technical effects of the apparatus, device, and medium will not be repeated here.

Those skilled in the art should understand that the embodiments of the present disclosure may be provided as a method, a system, or a computer program product. Therefore, the present disclosure may be in the form of full hardware embodiments, full software embodiments, or a combination thereof. Moreover, the present disclosure may be in the form of a computer program product that is implemented on one or more computer-usable storage medium (which includes, but is not limited to, magnetic disk storage, CD-ROM, optical storage) containing computer-usable program codes.

The present disclosure is described referring to the flowchart and/or block diagram of the method, apparatus (system) and computer program product according to the embodiments of the present disclosure. It should be understood that, each flow and/or block in the flow chart and/or block diagram and the combination of flow and/or block in the flow chart and/or block diagram may be realized via computer program instructions. Such computer program instructions may be provided to the processor of a general-purpose computer, special-purpose computer, a built-in processor or other programmable data processing devices to produce a machine, such that the instructions executed by the processor of a computer or other programmable data processing devices may produce a device for realizing the functions specified in one or more flows in the flow chart and/or one or more blocks in the block diagram.

Such computer program instructions may also be stored in a computer-readable storage that can guide a computer or other programmable data processing devices to work in a specific mode, such that the instructions stored in the computer-readable storage may produce a manufacture including a commander equipment, where the commander equipment may realize the functions specified in one or more flows of the flow chart and one or more blocks in the block diagram.

Such computer program instructions may also be loaded to a computer or other programmable data processing devices, such that a series of operational processes may be executed on the computer or other programmable devices to produce a computer-realized processing, and thereby the instructions executed on the computer or other programmable devices may provide a process for realizing the functions specified in one or more flows in the flow chart and/or one or more blocks in the block diagram.

In a typical configuration, the computing device includes one or more processors (CPU), an input/output interface, a network interface, and a memory.

The memory may include a non-permanent memory in a computer-readable medium, a random access memory (RAM) and/or a non-volatile memory, such as a read-only memory (ROM) or a flash memory (flash RAM). The memory is an example of a computer-readable medium.

The computer-readable medium may be permanent and non-permanent, or removable and non-removable media, which can achieve the information storage by any method or technology. The information may be computer-readable instructions, data structures, program modules, or other data. Examples of the computer storage medium include, but are not limited to, a phase change memory (PRAM), a static random access memory (SRAM), a dynamic random access memory (DRAM), other types of random access memory (RAM), read-only memory (ROM), an electrically erasable programmable read-only memory (EEPROM), a flash memory or other memory technologies, a CD-ROM, a digital versatile disc (DVD) or other optical storage, and a magnetic cassette tape. The magnetic tape storage or other magnetic storage devices or any other non-transmission medium may be used to store information that can be accessed by computing devices. According to the definition in this article, the computer-readable medium does not include transitory media, such as modulated data signals and carrier waves.

It shall also be noted that the terms “include”, “comprise” or any other variant thereof are intended to cover non-exclusive inclusion, such that a process, method, product or equipment including a series of elements not only includes those elements but also includes other elements that are not explicitly listed or elements inherent to the process, method, product, or equipment. If there are no more restrictions, the element defined by the expression “including a . . . ” does not exclude the case where the process, method, product, or equipment further includes other identical elements in addition to the element.

Described above are only examples of the present disclosure, and are not intended to limit the present disclosure. For those skilled in the art, the present disclosure may have various modifications and changes. Any modification, equivalent replacement, improvement, or the like made according to the spirit and principle of the present disclosure shall be regarded as within the claims of the present disclosure.

1. A method for accelerating computation of a convolutional neural network, comprising:
quantizing an original input tensor and an original convolution kernel by using a first function to acquire an input tensor and a convolution kernel that are in a fixed-point number form;
calculating respective quantization offsets of the input tensor and the convolution kernel that are in the fixed-point number form by using a second function, wherein the first function and the second function comprise respective quantization scaling coefficients, and respective conversion logics for converting a floating-point number into a fixed-point number;
calculating based on the quantization offsets a first convolution result of the input tensor and the convolution kernel that are in the fixed-point number form; and
calculating a second convolution result of the original input tensor and the original convolution kernel based on the quantization scaling coefficients and the first convolution result.

2. The method according to claim 1, wherein the quantization scaling coefficients comprise a first quantization coefficient for the original input tensor and a second quantization coefficient for the original convolution kernel;
the first quantization coefficient is calculated based on an end value of a specified quantized value range and an end value of the original input tensor, and/or
the second quantization coefficient is calculated based on the end value of the specified quantized value range and an end value of the original convolution kernel.

3. The method according to claim 2, wherein the end value of the quantized value range is calculated based on a specified quantization bit number.

4. The method according to claim 3, wherein the specified quantization bit number is the number w of quantization bits of a specified N-nary number, and the end value of the quantized value range is calculated according to following Formula:
Q_{low}=−N^{w-1};
Q_{high}=N^{w-1}−1;
wherein Q_{low} represents the minimum value of the quantized value range, and Q_{high} represents the maximum value of the quantized value range.

5. The method according to claim 2, wherein the first quantization coefficient is calculated according to Formula
$${S}_{X} = \frac{{Q}_{high} - {Q}_{l o w}}{{X}_{max} - {X}_{min}} ,$$
and/or
the second quantization coefficient is calculated according to Formula
$${S}_{W} = \frac{{Q}_{high} - {Q}_{l o w}}{{W}_{max} - {W}_{min}} ;$$
wherein S_{X} represents the first quantization coefficient; S_{W} represents the second quantization coefficient; Q_{low} represents the minimum value of the quantized value range; Q_{high} represents the maximum value of the quantized value range; Xₘᵢₙ represents the minimum value of the original input tensor; Xₘₐₓ represents a maximum value of the original input tensor; Wₘᵢₙ represents the minimum value of the original convolution kernel; and Wₘₐₓ represents the maximum value of the original convolution kernel.

6. The method according to claim 2, wherein in addition to the quantization scaling coefficient, the first function and/or the second function further comprises the minimum value of the quantized value range and the minimum value of an object to be quantized, wherein the object is the original input tensor or the original convolution kernel.

7. The method according to claim 6, wherein the first function is expressed as:
\dot{α}=round[S_{α}·(α−αₘᵢₙ)]+Q_{low};
wherein α represents the object; \dot{α} represents a quantized α; αₘᵢₙ represents a minimum value of α; S_{α} represents a quantization scaling coefficient for α; Q_{low} represents the minimum value of the quantized value range; and round represents a function for rounding the floating-point number to the fixed-point number.

8. The method according to claim 6, wherein the second function is expressed as:
B_{α}=round[−S_{α}·αₘᵢₙ]+Q_{low};
wherein B_{α} represents quantization offsets calculated for a quantized α; αₘᵢₙ represents a minimum value of α; S_{α} represents a quantization scaling coefficient for α; Q_{low} represents the minimum value of the quantized value range; and round represents a function for rounding the floating-point number to the fixed-point number.

9. The method according to claim 1, wherein calculating based on the quantization offsets the first convolution result of the input tensor and the convolution kernel that are in the fixed-point number form specifically comprises:
calculating the first convolution result of the input tensor and the convolution kernel that are in the fixed-point number form according to following Formula:
\dot{Y}=conv(\dot{X}−B_{X},\dot{W}−B_{W});
wherein \dot{Y} represents the first convolution result; \dot{X} represents the input tensor in the fixed-point number form; \dot{W} represents the convolution kernel in the fixed-point number form; B_{X} represents the quantization offset calculated for the input tensor in the fixed-point number form; B_{W} represents the quantization offset calculated for the convolution kernel in the fixed-point number form; and conv represents a convolution calculating function.

10. The method according to claim 9, wherein calculating the second convolution result of the original input tensor and the original convolution kernel based on the quantization scaling coefficients and the first convolution result specifically comprises:
calculating the second convolution result of the original input tensor and the original convolution kernel according to following Formula:
$$Y = \frac{\dot{Y}}{{S}_{X} \cdot {S}_{W}} ;$$
wherein Y represents the second convolution result; S_{X} represents the quantization scaling coefficient for the original input tensor; and S_{W} represents the quantization scaling coefficient for the original convolution kernel.

11. An apparatus for accelerating computation of a convolutional neural network, comprising:
a quantization module configured to quantize an original input tensor and an original convolution kernel by using a first function to acquire an input tensor and a convolution kernel that are in a fixed-point number form;
a quantization offset module configured to calculate by using a second function respective quantization offsets of the input tensor and the convolution kernel that are in the fixed-point number form, wherein the first function and the second function comprise respective quantization scaling coefficients, and respective conversion logics for converting a floating-point number into a fixed-point number;
a first convolution module configured to calculate based on the quantization offsets a first convolution result of the input tensor and the convolution kernel that are in the fixed-point number form; and
a second convolution module configured to calculate a second convolution result of the original input tensor and the original convolution kernel based on the quantization scaling coefficients and the first convolution result.

12. The apparatus according to claim 11, wherein the quantization scaling coefficients comprise a first quantization coefficient for the original input tensor and a second quantization coefficient for the original convolution kernel;
the first quantization coefficient is calculated based on an end value of a specified quantized value range and an end value of the original input tensor, and/or
the second quantization coefficient is calculated based on the end value of the specified quantized value range and an end value of the original convolution kernel.

13. The apparatus according to claim 12, wherein the end value of the quantized value range is calculated based on a specified quantization bit number.

14. The apparatus according to claim 13, wherein the specified quantization bit number is a number w of quantization bits of a specified N-nary number, and the quantization module calculates the end value of the quantized value range according to following Formula:
Q_{low}=−N^{w-1};
Q_{high}=N^{w-1}−1;
wherein Q_{low} represents a minimum value of the quantized value range, and Q_{high} represents a maximum value of the quantized value range.

15. The apparatus according to claim 12, wherein the first quantization coefficient is calculated according to Formula
$${S}_{X} = \frac{{Q}_{high} - {Q}_{l o w}}{{X}_{max} - {X}_{min}} ,$$
and/or
the second quantization coefficient is calculated according to Formula
$${S}_{W} = \frac{{Q}_{high} - {Q}_{l o w}}{{W}_{max} - {W}_{min}} ;$$
wherein S_{X} represents the first quantization coefficient; S_{W} represents the second quantization coefficient; Q_{low} represents the minimum value of the quantized value range; Q_{high} represents the maximum value of the quantized value range; Xₘᵢₙ represents a minimum value of the original input tensor; Xₘₐₓ represents a maximum value of the original input tensor; Wₘᵢₙ represents a minimum value of the original convolution kernel; and Wₘₐₓ represents a maximum value of the original convolution kernel.

16. The apparatus according to claim 12, wherein in addition to the quantization scaling coefficient, the first function and/or the second function further comprises a minimum value of the quantized value range and a minimum value of an object to be quantized;
wherein the object is the original input tensor or the original convolution kernel.

17. The apparatus according to claim 16, wherein the first function is expressed as:
\dot{α}=round[S_{α}·(α−αₘᵢₙ)]+Q_{low};
wherein α represents the object; \dot{α} represents a quantized α; αₘᵢₙ represents a minimum value of α; S_{α} represents a quantization scaling coefficient for α; Q_{low} represents the minimum value of the quantized value range; and round represents a function for rounding the floating-point number to the fixed-point number.

18. The apparatus according to claim 16, wherein the second function is expressed as:
B_{α}=round[−S_{α}·αₘᵢₙ]+Q_{low};
wherein B_{α} represents quantization offsets calculated for a quantized α; αₘᵢₙ represents a minimum value of α; S_{α}, represents a quantization scaling coefficient for α; Q_{low} represents the minimum value of the quantized value range; and round represents a function for rounding the floating-point number to the fixed-point number.

19. The apparatus according to claim 11, wherein calculating the first convolution result of the input tensor and the convolution kernel that are in the fixed-point number form by the first convolution module based on the quantization offsets comprises:
calculating the first convolution result of the input tensor and the convolution kernel that are in the fixed-point number form by the first convolution module according to following Formula:
\dot{Y}=conv(\dot{X}−B_{X},\dot{W}−B_{W});
wherein \dot{Y} represents the first convolution result; \dot{X} represents the input tensor in the fixed-point number form; \dot{W} represents the convolution kernel in the fixed-point number form; B_{X} represents the quantization offset calculated for the input tensor in the fixed-point number form; B_{W} represents the quantization offset calculated for the convolution kernel in the fixed-point number form; and conv represents a convolution calculating function.

20. (canceled)

21. (canceled)

22. A non-volatile computer storage medium for accelerating computation of a convolutional neural network, having computer-executable instructions stored therein, the computer-executable instructions being configured to:
quantize an original input tensor and an original convolution kernel by using a first function to acquire an input tensor and a convolution kernel that are in a fixed-point number form;
calculate respective quantization offsets of the input tensor and the convolution kernel that are in the fixed-point number form by using a second function, wherein the first function and the second function comprise respective quantization scaling coefficients, and respective conversion logics for converting a floating-point number into a fixed-point number;
calculate a first convolution result of the input tensor and the convolution kernel that are in the fixed-point number form based on the quantization offsets; and
calculate a second convolution result of the original input tensor and the original convolution kernel based on the quantization scaling coefficients and the first convolution result.
